(19) United States
(12) Patent Application Publication
(10) Pub. No.: US 2024/0429188 A1
(43) Pub. Date: Dec. 26, 2024

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Jun TANAKA, Kuwana Mie (JP)

(21) Appl. No.: 18/747,288

(22) Filed: Jun. 18, 2024

(30) Foreign Application Priority Data
Jun. 20, 2023 (JP) 2023-100613

(51) Int. Cl. H01L 23/00; H01L 23/31; H01L 23/48; H01L 23/498; H01L 23/538; H01L 25/065; H01L 25/10; H10B 80/00

(52) U.S. Cl. CPC H01L 24/14; H01L 23/481; H01L 23/5383; H01L 24/16; H01L 24/32; H01L 24/92; H01L 25/0657; H01L 25/105; H01L 23/3135; H01L 23/49816; H01L 24/81; H01L 2224/1403; H01L 2224/14505; H01L 2224/16145; H01L 2224/16225; H01L 2224/32225; H01L 2224/81815; H01L 2224/92225; H01L 2224/92242; H10B 80/00

(57) ABSTRACT

A semiconductor device includes a substrate, a first semiconductor chip, an adhesive layer, a second semiconductor chip, a first joint, and a second joint. The adhesive layer fixes the substrate to the first semiconductor chip. The second semiconductor chip includes a first region overlapping the first semiconductor chip in a thickness direction of the substrate and a second region excluding the first region. The first joint is disposed between the first semiconductor chip and the first region of the second semiconductor chip and electrically connects the first semiconductor chip to the second semiconductor chip. The second joint is disposed between the substrate and the second region of the second semiconductor chip, is larger than the first joint in volume, and electrically connects the substrate to the second semiconductor chip. A fusion point of the first joint is lower than a fusion point of the second joint.

### CROSS-REFERENCE TO RELATED APPLICATION(S)

This application is based upon and claims the benefit of priority from Japanese Patent Application No. 2023-100613, filed Jun. 20, 2023, the entire contents of which are incorporated herein by reference.

### FIELD

Embodiments described herein relate generally to a semiconductor device and a method of manufacturing the semiconductor device.

### BACKGROUND

A semiconductor device including a substrate, a first semiconductor chip, and a second semiconductor chip connected to the substrate and the first semiconductor chip is known.

### DESCRIPTION OF THE DRAWINGS

FIG. 1 is a sectional view illustrating a semiconductor device according to a first embodiment.

FIG. 2 is a partially expanded sectional view of the semiconductor device.

FIG. 3 is a partially exploded sectional view of the semiconductor device illustrated in FIG. 2.

FIG. 4 is an expanded sectional view of a region surrounded by a line F4 in FIG. 2.

FIG. 5 is a diagram illustrating properties of fusion points.

FIG. 6 is a diagram illustrating a flow of a method of manufacturing the semiconductor device.

FIGS. 7-9 are sectional views illustrating the method of manufacturing the semiconductor device.

FIG. 10 is a sectional view illustrating a method of manufacturing a semiconductor device according to a modified example of the first embodiment.

FIG. 11 is a partial sectional view illustrating a semiconductor device according to a second embodiment.

FIG. 12 is a diagram illustrating a method of manufacturing the semiconductor device according to the second embodiment.

FIG. 13 is a partial sectional view illustrating a semiconductor device according to a third embodiment.

FIG. 14 is a sectional view illustrating a semiconductor device according to a modified example of the first to third embodiments.

### DETAILED DESCRIPTION

Embodiments of a semiconductor device described herein achieve a reduction in occurrence of a failure.

In general, according to one embodiment, a semiconductor device includes a substrate, a first semiconductor chip, an adhesive layer, a second semiconductor chip, a first joint, and a second joint. The adhesive layer is provided between the substrate and the first semiconductor chip and fixes the substrate to the first semiconductor chip. The second semiconductor chip is disposed opposite to the substrate with respect to the first semiconductor chip and includes a first region overlapping the first semiconductor chip in a first direction that is a thickness direction of the substrate and a second region excluding the first region. The first joint is disposed between the first semiconductor chip and the first region of the second semiconductor chip and electrically connects the first semiconductor chip to the second semiconductor chip. The second joint is disposed between the substrate and the second region of the second semiconductor chip and electrically connects the substrate to the second semiconductor chip. A fusion point of the first joint is lower than a fusion point of the second joint.

Hereinafter, a semiconductor device and a method of manufacturing the semiconductor device according to embodiments will be described with reference to the drawings. In the following description, the same reference numerals are given to configurations that have the same or similar functions. Repeated description of such configurations will be omitted in some cases.

In the present application, terms are defined as follows. “Parallel”, “orthogonal”, and “same” may include “substantially parallel”, “substantially orthogonal”, and “substantially same”, respectively. “Connection” is not limited to mechanical connection and may include electrical connection. That is, “connection” is not limited to direct connection of two elements to be connected and may include connection of two elements to be connected via another element. In the present application, a “width” means a “maximum width” when the width is different depending on position.

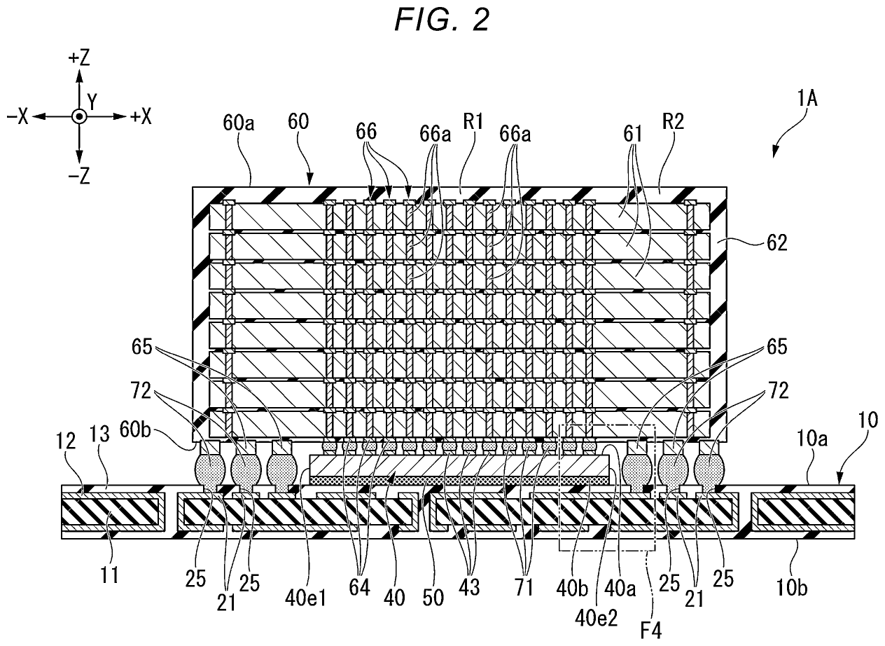

A +X direction, a −X direction, a Y direction, a +Z direction, and a −Z direction are defined as follows. The +X direction, the −X direction, and the Y direction are directions oriented along a first surface 10a of a package substrate 10 to be described below (see FIG. 2). The +X direction is a direction oriented from a first end 40e1 to a second end 40e2 of a first semiconductor chip 40 to be described below. The −X direction is a direction opposite to the +X direction. When the +X direction and the −X direction are not distinguished from each other, the +X direction and the −X direction are simply referred to as an “X direction”. The Y direction is a direction intersecting (for example, orthogonal to) the X direction. The +Z direction and the −Z direction are directions intersecting (for example, orthogonal to) the X direction and the Y direction. The +Z direction is a thickness direction of the package substrate 10 and is a direction that points away from the package substrate 10 towards the first semiconductor chip 40. The −Z direction is a direction opposite to the +Z direction. When the +Z direction and the −Z direction are not distinguished from each other, the +Z direction and the −Z direction are simply referred to as a “Z direction”. The Z direction is an example of a “first direction”. The X direction is an example of a “second direction”. A −X direction side is an example of a “first side”. A+X direction side is an example of a “second side”.

### First Embodiment

### 1. Configuration of Semiconductor Device

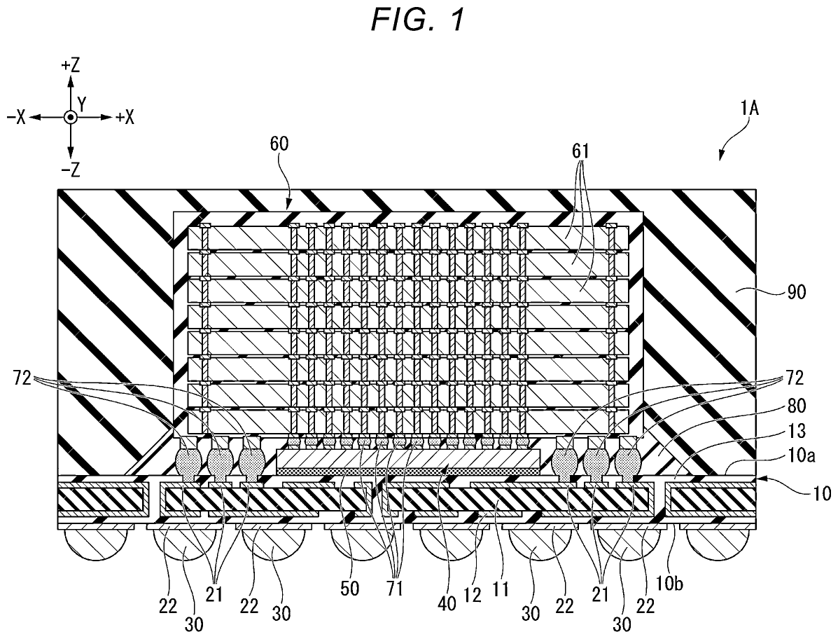

First, configurations common to first to third embodiments will be described with reference to FIGS. 1 to 4.

FIG. 1 is a sectional view illustrating a semiconductor device 1A according to a first embodiment. Hereinafter, an example in which the semiconductor device 1A is a semiconductor storage device including a plurality of semiconductor memory components 61 will be described. It should be noted that the following description of the embodiments does not limit the scope of the present disclosure.

As illustrated in FIG. 1, the semiconductor device 1A includes, for example, a package substrate 10, a plurality of connection terminals 30, a first semiconductor chip 40, an adhesive layer 50, a second semiconductor chip 60, a plurality of first joints 71, a plurality of second joints 72, an insulating layer 80, and a sealing resin portion 90.

### 1.1 Package Substrate

The package substrate 10 is a member that forms a base of the semiconductor device 1A. The package substrate 10 includes a first surface 10a and a second surface 10b disposed opposite to the first surface 10a. The first surface 10a is a surface oriented in the +Z direction. The second surface 10b is a surface oriented in the −Z direction. The package substrate 10 is a printed substrate. The package substrate 10 includes, for example, an insulating base material 11, a conductive pattern 12, and a solder resist layer 13.

The insulating base material 11 is an insulating hard member formed of an insulating material such as glass epoxy resin or polyimide. The insulating base material 11 forms a main part of the package substrate 10.

The conductive pattern 12 is a conductive portion provided on a surface or an inner portion of the insulating base material 11. The conductive pattern 12 forms a wiring of the printed substrate. The conductive pattern 12 includes a plurality of pads 21 disposed on the first surface 10a and a plurality of pads 22 disposed on the second surface 10b.

The solder resist layer 13 is an insulating layer provided on a surface of the package substrate 10. The solder resist layer 13 includes a plurality of openings 25 (see FIG. 2). The plurality of openings 25 are provided on the first surface 10a of the package substrate 10 to expose the plurality of pads 21 outside of the package substrate 10. The plurality of openings 25 have a one-to-one relationship with the plurality of pads 21. In the present application, “exposing a pad” means exposing at least part of the pad. That is, “exposing a pad” can correspond to a case in which a middle portion of the pad is exposed through the opening with a circumferential end of the pad covered with the solder resist layer.

### 1.2 Connection Terminal

The plurality of connection terminals 30 are terminals exposed outside of the semiconductor device 1A. The plurality of connection terminals 30 are electrically connected to an external device (not illustrated) (hereinafter referred to as a “host device”) disposed outside of the semiconductor device 1A. The plurality of connection terminals 30 are provided on the second surface 10b of the package substrate 10 and joined to the plurality of pads 22. The semiconductor device 1A is, for example, a ball grid array (BGA) type semiconductor package. The plurality of connection terminals 30 are a plurality of solder joints (for example, solder bumps) located in the X and Y directions on the second surface 10b of the package substrate 10.

### 1.3 First Semiconductor Chip

The first semiconductor chip 40 is a semiconductor chip including one or more circuits. The first semiconductor chip 40 includes at least one of a control circuit that controls the second semiconductor chip 60 and an interface circuit provided between the package substrate 10 and the second semiconductor chip 60.

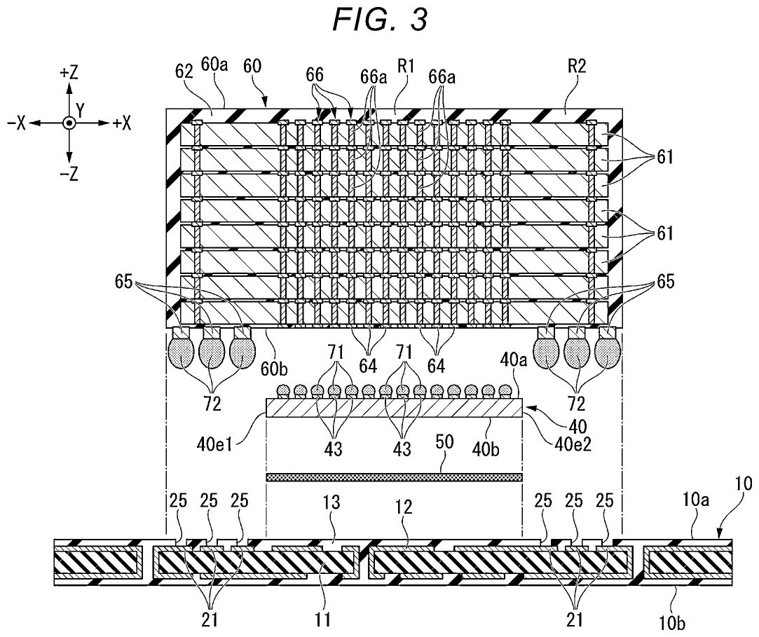

FIG. 2 is a partially expanded sectional view of the semiconductor device 1A. In FIG. 2, to facilitate description, the plurality of connection terminals 30, the insulating layer 80, and the sealing resin portion 90 are not illustrated. FIG. 3 is a partially exploded sectional view of the semiconductor device 1A illustrated in FIG. 2.

As illustrated in FIG. 3, the first semiconductor chip 40 includes a first surface 40a and a second surface 40b disposed opposite to the first surface 40a. The first surface 40a is a surface oriented in the +Z direction. The second surface 40b is a surface oriented in the −Z direction. The first semiconductor chip 40 includes a first end 40e1 disposed on the −X direction side and a second end 40e2 disposed on the +X direction side.

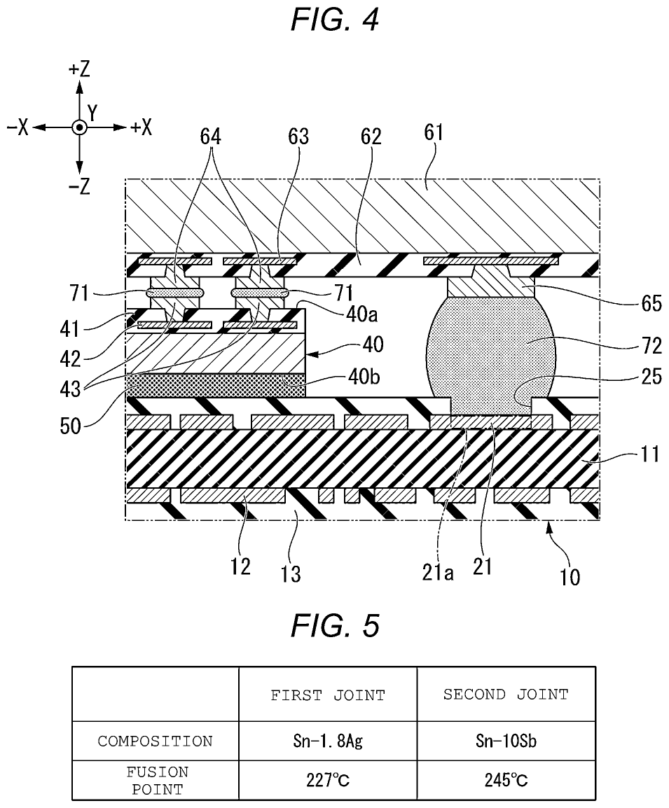

The first semiconductor chip 40 includes, for example, an insulating portion 41 (see FIG. 4), a wiring layer 42 (see FIG. 4), and a plurality of pads 43. For example, the insulating portion 41 is provided at an end of the first semiconductor chip 40 on the +Z direction side. The wiring layer 42 is provided in the insulating portion 41. The plurality of pads 43 are provided on the first surface 40a and are electrically connected to a circuit in the first semiconductor chip 40 via the wiring layer 42. The plurality of pads 43 are arranged in parallel in the X and Y directions.

### 1.4 Adhesive Layer

Referring back to FIG. 2, the adhesive layer 50 will be described.

The adhesive layer 50 is an adhesive portion fixing the package substrate 10 and the first semiconductor chip 40. For example, the adhesive layer 50 is provided along the second surface 40b of the first semiconductor chip 40. The adhesive layer 50 is provided between the first surface 10a of the package substrate 10 and the second surface 40b of the first semiconductor chip 40 and fixes the first surface 10a of the package substrate 10 to the second surface 40b of the first semiconductor chip 40. For example, the adhesive layer 50 is provided along at least one-half of the width of the second surface 40b of the first semiconductor chip 40 in the X direction. For example, the adhesive layer 50 is provided across the first end 40e1 and the second end 40c2 of the first semiconductor chip 40. For example, the adhesive layer 50 is formed by an adhesive such as a die-attach film. A thickness of the adhesive layer 50 in the Z direction is, for example, 10 μm.

Hereinafter, an example in which a thermosetting adhesive (for example, a thermosetting die-attach film) is used as the adhesive layer 50 will be described. Here, the adhesive layer 50 is not limited to the thermosetting adhesive and may be formed of a thermosoftening adhesive (for example, a thermosoftening die-attach film) or the like. In the present application, “curing” is not limited to curing performed through heating a thermosetting adhesive at a predetermined temperature (cure temperature) or more, and can correspond to curing by heating and softening a thermosoftening adhesive at a predetermined temperature (softening temperature) or more and then cooling, or the like.

### 1.5 Second Semiconductor Chip

The second semiconductor chip 60 is a semiconductor chip including one or more semiconductor components. The second semiconductor chip 60 includes, for example, one or more semiconductor memory components 61 as one or more semiconductor components. The semiconductor memory component 61 may be, for example, a nonvolatile semiconductor memory component such as a NAND memory or may be a volatile semiconductor memory component such as a dynamic random access memory (DRAM).

As illustrated in FIG. 2, the second semiconductor chip 60 includes a first surface 60a and a second surface 60b disposed opposite to the first surface 60a. The first surface 60a is a surface oriented in the +Z direction. The second surface 60b is a surface oriented in the −Z direction. The second semiconductor chip 60 includes, for example, a plurality of semiconductor memory components 61, an insulating portion 62, a wiring layer 63 (see FIG. 4), a plurality of small pads 64, and a plurality of large pads 65.

For example, the plurality of semiconductor memory components 61 are stacked and disposed in the Z direction. Each semiconductor memory component 61 includes a plurality of electrical connection portions 66a separately provided in the X direction. Each electrical connection portion 66a penetrates through the semiconductor memory component 61 in the Z direction. The electrical connection portion 66a provided in one semiconductor memory component 61 is connected to the electrical connection portion 66a provided in another semiconductor memory component 61 adjacent in the Z direction. Accordingly, a plurality of through-silicon vias (TSVs) 66 are formed penetrating through the plurality of semiconductor memory components 61 in the Z direction. The plurality of semiconductor memory components 61 are electrically connected to the wiring layer 63 of the second semiconductor chip 60 via the plurality of through-silicon vias 66.

The insulating portion 62 is a sealing resin portion that seals the plurality of semiconductor memory components 61. The insulating portion 62 forms the exterior dimensions of the second semiconductor chip 60. The wiring layer 63 is provided in the insulating portion 62 at an end of the second semiconductor chip 60 on the −Z direction side (see FIG. 4). The plurality of small pads 64 and the plurality of large pads 65 are provided on the second surface 60b and are electrically connected to the wiring layer 63. The small pads 64 and the large pads 65 will be described in detail below.

As illustrated in FIG. 2, the second semiconductor chip 60 is disposed opposite to the package substrate 10 with respect to the first semiconductor chip 40. A width of the second semiconductor chip 60 in the X direction is greater than a width of the first semiconductor chip 40 in the X direction. The second semiconductor chip 60 includes a first region R1 and a second region R2. The first region R1 is a region overlapping the first semiconductor chip 40 in the Z direction. The second region R2 is a region excluding the first region R1.

The plurality of small pads 64 are provided in the first region R1 of the second semiconductor chip 60 and are arranged in parallel in the X and Y directions. The plurality of small pads 64 respectively face the plurality of pads 43 of the first semiconductor chip 40 in the Z direction. For example, a size of the small pad 64 is the same as a size of the pad 43 of the first semiconductor chip 40.

The plurality of large pads 65 are provided in the second region R2 of the second semiconductor chip 60 and are arranged in parallel in the X and Y directions. The plurality of large pads 65 respectively face the plurality of pads 21 of the package substrate 10 in the Z direction. The large pad 65 is larger (in volume and maximum cross-section taken in the XY plane) than the small pad 64.

### 1.6 First Joint

The plurality of first joints 71 are electrical connection portions that electrically connect the first semiconductor chip 40 to the second semiconductor chip 60. The plurality of first joints 71 are disposed between the first semiconductor chip 40 and the first region R1 of the second semiconductor chip 60. The plurality of first joints 71 are arranged in parallel in the X and Y directions. Each first joint 71 is connected (joined) to the pad 43 of the first semiconductor chip 40 and is connected (joined) to the small pad 64 of the second semiconductor chip 60. Each first joint 71 is, for example, a solder joint (for example, a solder bump).

### 1.7 Second Joint

The plurality of second joints 72 are electrical connection portions that electrically connect the package substrate 10 to the second semiconductor chip 60. The plurality of second joints 72 are disposed between the package substrate 10 and the second region R2 of the second semiconductor chip 60. The plurality of second joints 72 are arranged in parallel in the X and Y directions. The second joint 72 is larger than the first joint 71. Each second joint 72 is connected (joined) to the pad 21 of the package substrate 10 and is connected (joined) to the large pad 65 of the second semiconductor chip 60. Each second joint 72 is, for example, a solder joint (for example, a solder bump).

FIG. 4 is an expanded sectional view of a region surrounded by a line F4 in FIG. 2. In the embodiment, the pad 21 of the package substrate 10 is larger than the opening 25 of the package substrate 10. The pad 21 includes an exposed portion 21a exposed to the opening 25. A part of the second joint 72 is disposed in the opening 25 of the package substrate 10 and is joined to the exposed portion 21a of the pad 21.

### 1.8 Insulating Layer

Next, referring back to FIG. 1, the insulating layer 80 will be described.

The insulating layer 80 is an underfill layer provided between the package substrate 10 and the second semiconductor chip 60. For example, the insulating layer 80 is provided between the first surface 10a of the package substrate 10 and the second surface 60b of the second semiconductor chip 60 and between the first surface 40a of the first semiconductor chip 40 and the second surface 60b of the second semiconductor chip 60. The insulating layer 80 electrically insulates the plurality of first joints 71 from each other and electrically insulates the plurality of second joints 72 from each other.

### 1.9 Scaling Resin Portion

The sealing resin portion 90 is a sealing resin portion that seals the second semiconductor chip 60 and the insulating layer 80. The sealing resin portion 90 integrally covers a part of the first surface 10a of the package substrate 10, the second semiconductor chip 60, and the insulating layer 80. The sealing resin portion 90 forms a part of the exterior dimensions of the semiconductor device 1A.

### 2. Configuration According to First Embodiment

Next, a configuration according to the first embodiment will be described.

In the first embodiment, a fusion point of the first joint 71 is different from a fusion point of the second joint 72. Hereinafter, the contents will be described in detail.

FIG. 5 is a diagram illustrating properties of fusion points that include the first joint 71 and the second joint 72. In the embodiment, a material of the first joint 71 is different from a material of the second joint 72, and thus the fusion point of the first joint 71 is lower than the fusion point of the second joint 72. For example, the fusion point of the first joint 71 is lower by 5° C. or more than the fusion point of the second joint 72. In the embodiment, the fusion point of the first joint 71 is lower by 10° C. or more than the fusion point of the second joint 72.

The material of the first joint 71 is, for example, Sn—Ag (a tin-silver alloy). An example of the material of the first joint 71 is Sn-1.8Ag (a tin-silver alloy, in which content of tin is 98.2% and content of silver is 1.8%). The fusion point of the first joint 71 is, for example, 227° C. It should be noted that the material of the first joint 71 is not limited to the foregoing example.

The material of the second joint 72 is, for example, Sn—Sb (a tin-antimony alloy). An example of the material of the second joint 72 is Sn-10Sb (a tin-antimony alloy, in which content of tin is 90% and content of antimony is 10%). The fusion point of the second joint 72 is, for example, 245° C. It should be noted that the material of the second joint 72 is not limited to the foregoing example.

### 3. Method of Manufacturing Semiconductor Device

Next, a method of manufacturing the semiconductor device 1A will be described.

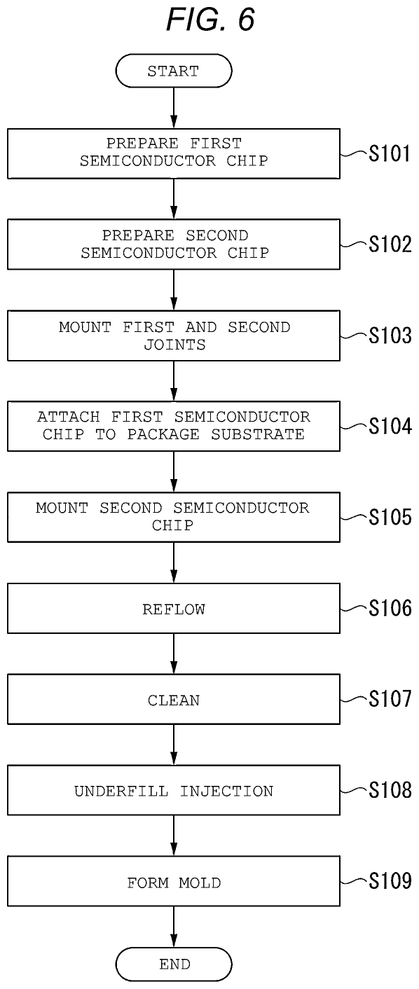

First, common portions between first to third embodiments will be described with reference to FIGS. 6 to 8.

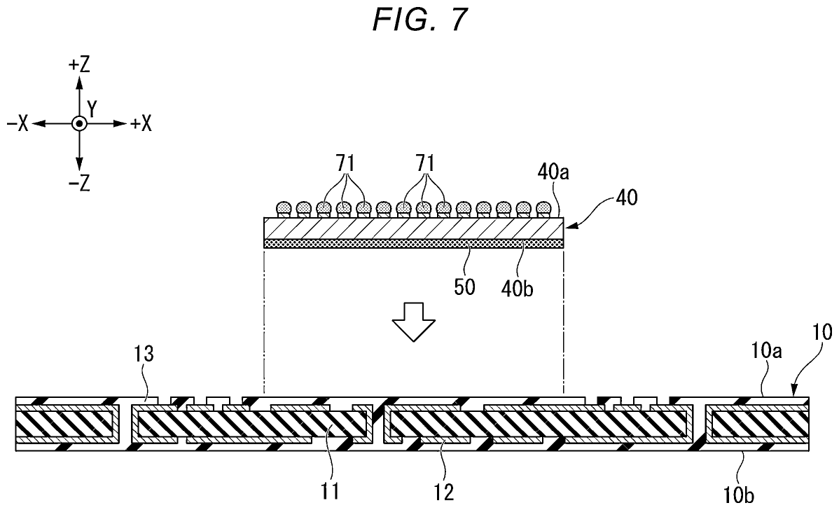

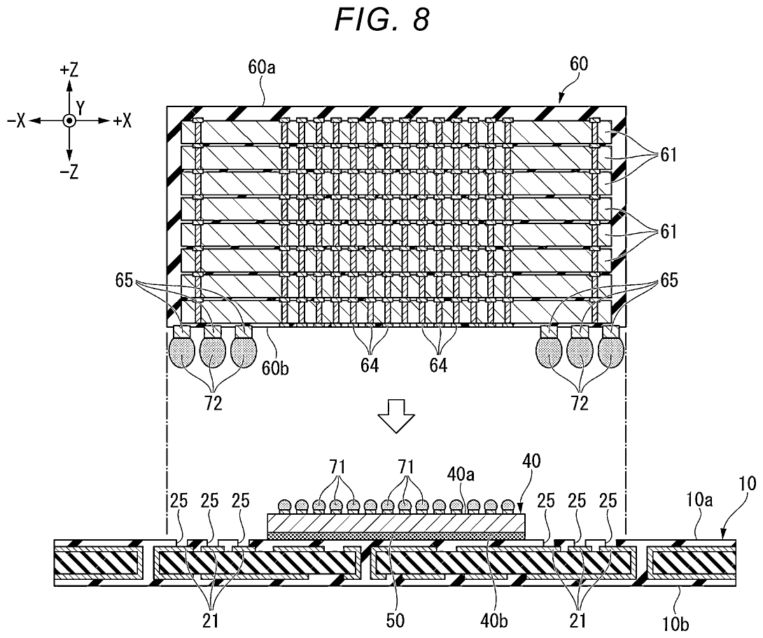

FIG. 6 is a diagram illustrating a flow of a method of manufacturing the semiconductor device 1A according to the embodiment. FIGS. 7 and 8 are sectional views illustrating the method of manufacturing the semiconductor device 1A according to the embodiment.

First, the first semiconductor chip 40 is prepared (S101). The second semiconductor 60 is prepared by manufacturing the second semiconductor chip 60 (S102). For example, the second semiconductor chip 60 is manufactured by stacking the plurality of semiconductor memory components 61, sealing the plurality of semiconductor memory components 61 by the insulating portion 62, and providing the small pads 64 and the large pads 65.

Subsequently, a process of mounting the first joints 71 and the second joints 72 is performed (S103). In the embodiment, the plurality of first joints 71 are mounted on the plurality of pads 43 of the first semiconductor chip 40. The plurality of second joints 72 are mounted on the plurality of large pads 65 of the second semiconductor chip 60. Alternatively, the plurality of first joints 71 may be mounted on the plurality of small pads 64 of the second semiconductor chip 60 instead of being mounted on the plurality of pads 43 of the first semiconductor chip 40.

Subsequently, the first semiconductor chip 40 is mounted on the package substrate 10 (S104). For example, the second surface 40b of the first semiconductor chip 40 is fixed to the first surface 10a of the package substrate 10 using the adhesive layer (adhesive) 50 (see FIG. 7). The adhesive layer 50 is first provided on the second surface 40b of the first semiconductor chip 40, and then is mounted on the package substrate 10 together with the first semiconductor chip 40. Alternatively, after the adhesive layer 50 is provided on the package substrate 10, the first semiconductor chip 40 may be mounted on the adhesive layer 50 on the package substrate 10.

Subsequently, the second semiconductor chip 60 is mounted on the package substrate 10 and the first semiconductor chip 40 (S105). For example, while the plurality of first joints 71 are disposed between the first region R1 of the second semiconductor chip 60 and the first semiconductor chip 40 and the plurality of second joints 72 are disposed between the second region R2 of the second semiconductor chip 60 and the package substrate 10, the second semiconductor chip 60 is placed on the first semiconductor chip 40 and the package substrate 10 with the plurality of first joints 71 and the plurality of second joints 72 interposed therebetween (see FIG. 8).

Subsequently, a reflow process is performed (S106). Accordingly, the plurality of small pads 64 of the second semiconductor chip 60 are connected (joined) to the plurality of pads 43 of the first semiconductor chip 40 by the plurality of first joints 71. The plurality of large pads 65 of the second semiconductor chip 60 are connected (joined) to the package substrate 10 by the plurality of second joints 72.

Next, a cleaning process is performed (S107). Next, the insulating layer 80 is formed by supplying an insulating material for the insulating layer 80 (S108). Next, the scaling resin portion 90 is formed by supplying an insulating material for the sealing resin portion 90 (S109). Accordingly, a series of manufacturing processes is completed.

### 4. Method of Manufacturing Semiconductor Device According to First Embodiment

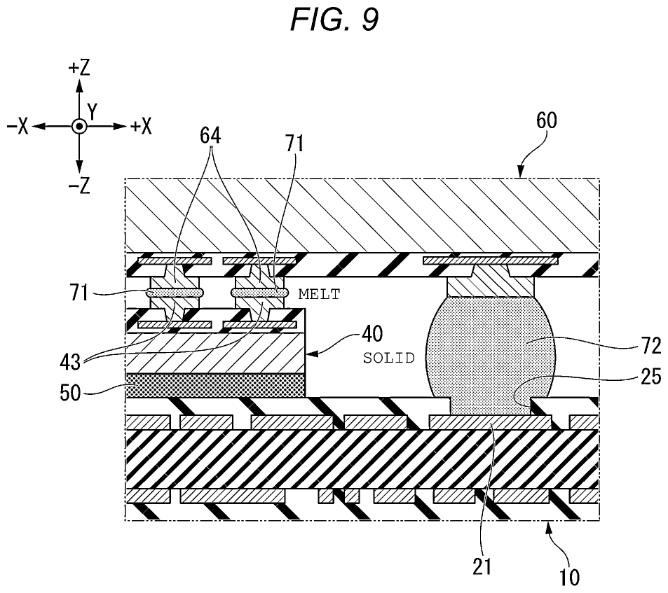

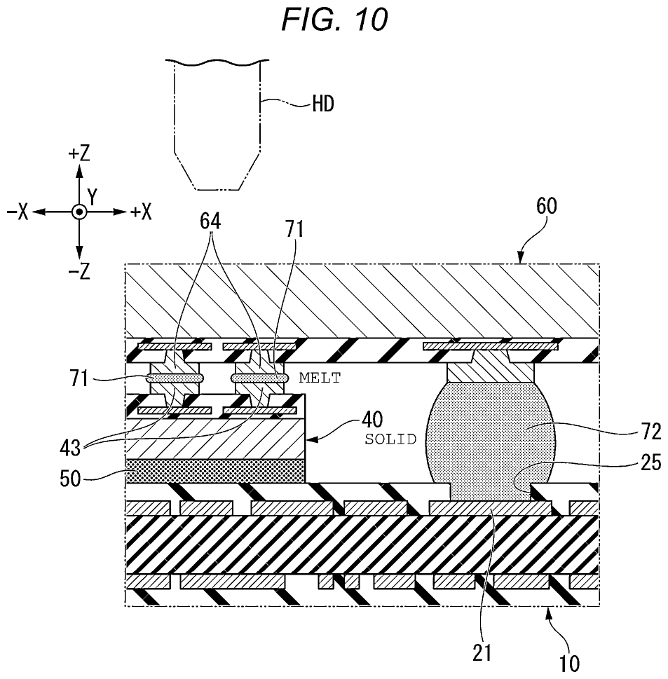

FIG. 9 is a sectional view illustrating the manufacturing method according to the first embodiment.

In the first embodiment, the fusion point of the first joint 71 is lower than the fusion point of the second joint 72. Therefore, in the reflow process, by fusing the plurality of first joints 71 and the plurality of second joints 72 and then gradually lowering the temperature, the plurality of second joints 72 are solidified while the plurality of joints 71 are fused.

Then, after the solidification of the plurality of second joints 72 is completed, solidification of the plurality of first joints 71 is completed. In the present application, “completion of solidification of first joints after completion of solidification of second joints” is not limited to a case in which the first joints 71 start to be solidified after the completion of the solidification of the second joints 72 and can include a case in which the first joints 71 start to be solidified even before the completion of the solidification of the second joints 72.

### 5. Advantages of First Embodiment

As a first comparative example, a configuration is conceivable in which after the first semiconductor chip 40 is first fixed to the rear surface of the second semiconductor chip 60 with the plurality of first joints 71 interposed therebetween and the first semiconductor chip 40 is integrated with the second semiconductor chip 60, the second semiconductor chip 60 is fixed to the package substrate 10 with the plurality of second joints 72 interposed therebetween. In such configuration, it is necessary to provide a gap of about 30 μm as a gap for injecting an insulating material of an underfill layer between the first semiconductor chip 40 and the package substrate 10. Therefore, it is difficult to make a thin semiconductor device. Reflow process is necessary for both the process of fixing the first semiconductor chip 40 to the rear surface of the second semiconductor chip 60 with the plurality of first joints 71 interposed therebetween and the process of fixing the second semiconductor chip 60 to the package substrate 10 with the plurality of second joints 72 interposed therebetween, and thus it is difficult to shorten the manufacturing process.

In the embodiment, however, the semiconductor device 1A includes the package substrate 10, the first semiconductor chip 40, the adhesive layer 50, the second semiconductor chip 60, the first joints 71, and the second joints 72. The adhesive layer 50 is provided between the package substrate 10 and the first semiconductor chip 40 to fix the package substrate 10 to the first semiconductor chip 40. The second semiconductor chip 60 is disposed opposite to the package substrate 10 with respect to the first semiconductor chip 40 and includes the first region R1 overlapping the first semiconductor chip 40 in the Z direction and the second region R2 excluding the first region R1. The first joints 71 are disposed between the first semiconductor chip 40 and the first region R1 of the second semiconductor chip 60 and electrically connects the first semiconductor chip 40 to the second semiconductor chip 60. The second joints 72 are disposed between the package substrate 10 and the second region R2 of the second semiconductor chip 60, are larger than the first joints 71, and electrically connect the package substrate 10 to the second semiconductor chip 60.

In such configuration, a distance between the first semiconductor chip 40 and the package substrate 10 in the Z direction can be made to be as small as the thickness of the adhesive layer 50 (for example, about 10 μm). Therefore, it is possible to make a thin semiconductor device 1A. In the foregoing configuration, through one reflow process, it is possible to perform the process of fixing the second semiconductor chip 60 to the first semiconductor chip 40 with the first joints 71 interposed therebetween and the process of fixing the second semiconductor chip 60 to the package substrate 10 with the second joints 72 interposed therebetween. Therefore, it is possible to shorten the manufacturing process.

Here, as a second comparative example, a case is conceivable in which the first joints 71 and the second joints 72 are simultaneously solidified when performing the process of fixing the second semiconductor chip 60 to the first semiconductor chip 40 with the first joints 71 interposed therebetween and the process of fixing the second semiconductor chip 60 to the package substrate 10 with the second joints 72 interposed therebetween by one reflow process. Here, when a positional deviation occurs at the position at which the first semiconductor chip 40 is mounted on the package substrate 10, there is a likelihood that a connection failure of the first joints 71 occurs due to a difference in volume between the first joints 71 and the second joints 72. That is, the second joint 72 is larger than the first joint 71. Therefore, when the first joints 71 and the second joints 72 are solidified in the reflow process, tensile forces of the second joints 72 are dominant compared to tensile forces of the first joints 71 and shearing force for moving the second semiconductor chip 60 in the X or Y direction is applied to the first semiconductor chip 40. Therefore, when the first joints 71 are solidified earlier than the second joints 72, there is a likelihood that the first joints 71 are fractured due to the shearing force.

Meanwhile, in the embodiment, the fusion point of the first joint 71 is set to be lower than the fusion point of the second joint 72. In such configuration, the first joints 71 are prevented from being solidified earlier than the second joints 72. When the shearing force is applied to the first joints 71 due to the tensile forces of the second joints 72, the first joints 71 can be deformed in response to the shearing force. Therefore, the first joints 71 can be prevented from being fractured due to the shearing force. Accordingly, it is possible to reduce occurrence of a failure of the semiconductor device 1A.

In the embodiment, the fusion point of the first joint 71 is lower than the fusion point of the second joint 72 by 5° C. or more. In such configuration, even when a variation in temperature occurs in the semiconductor device 1A, the first joints 71 can be more reliably prevented from being solidified earlier than the second joints 72. An experiment by the present inventors shows that a variation in temperature occurring in the semiconductor device 1A is less than 5° C.

### Modified Example of First Embodiment

Next, a modified example of the first embodiment will be described.

FIG. 10 is a sectional view illustrating a method of manufacturing a semiconductor device according to a modified example of the first embodiment. In the above-described embodiment, since the fusion point of the first joints 71 is lower than the fusion point of the second joints 72, the solidification of the first joints 71 is completed after the solidification of the second joints 72 is completed.

Instead of or in addition to the above-described configuration, in the modified example, a heating device HD (for example, a laser reflow device) is used to maintain a difference in temperature between the second joints 72 and the first joints 71. That is, the solidification of the second joints 72 is completed by lowering the temperature of the second joints 72 while the temperature of the first joints 71 is maintained or a reduction in temperature is prevented by the heating device HD. In such configuration, after the solidification of the second joints 72 is completed, the solidification of the first joints 71 can be completed. In the modified example, the fusion point of the first joints 71 may be the same as the fusion point of the second joints 72. That is, the material of the first joints 71 may be the same as the material of the second joints 72.

### Second Embodiment

Next, a second embodiment will be described. The second embodiment is different from the first embodiment in that the first semiconductor chip 40 is permitted to be inclined along the second semiconductor chip 60 by the adhesive layer 50. Configurations other than configurations to be described below are the same as those of the first embodiment.

### Configuration According to Second Embodiment

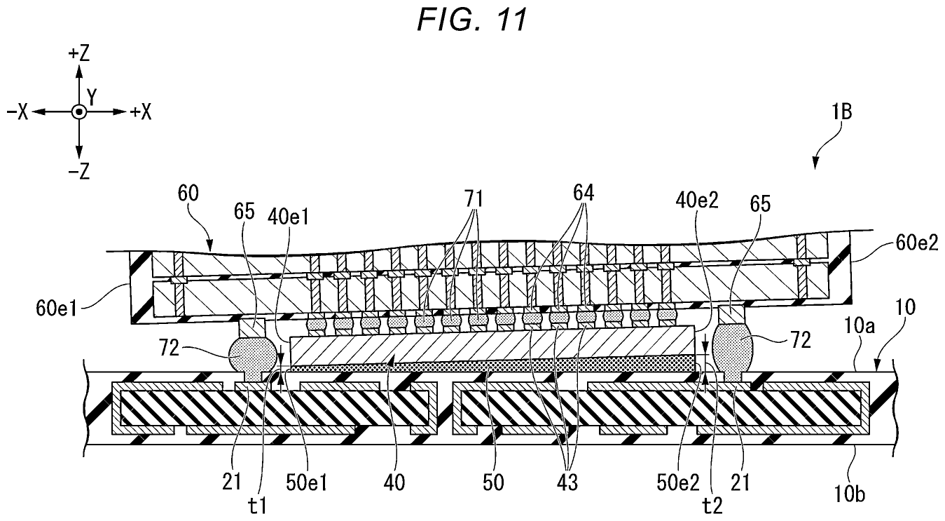

FIG. 11 is a partial sectional view illustrating a semiconductor device 1B according to the second embodiment. In the embodiment, the second semiconductor chip 60 is disposed obliquely with respect to the package substrate 10. The second semiconductor chip 60 includes an end 60e1 on the −X direction side and an end 60e2 on the +X direction side. A distance between the end 60e2 of the second semiconductor chip 60 on the +X direction side and the package substrate 10 is greater than a distance between the end 60e1 of the second semiconductor chip 60 on the −X direction side and the package substrate 10.

The first semiconductor chip 40 is disposed obliquely with respect to the package substrate 10. The first semiconductor chip 40 includes an end 40e1 on the −X direction side and an end 40c2 on the +X direction side. A distance between the end 40e2 of the first semiconductor chip 40 on the +X direction side and the package substrate 10 is greater than a distance between the end 40e1 of the first semiconductor chip 40 on the −X direction side and the package substrate 10. The first semiconductor chip 40 is supported obliquely by, for example, the adhesive layer 50 to be described below and is disposed obliquely at an angle equal to or greater than 0.01° and equal to or smaller than 1.00° with respect to the package substrate 10.

The adhesive layer 50 includes an end 50e1 on the −X direction side and on end 50c2 in the +X direction side. A thickness t2 in the Z direction of the end 50e2 of the adhesive layer 50 on the +X direction side is greater than a thickness t1 in the Z direction of the end 50e1 of the adhesive layer 50 on the −X direction side. The thickness t2 in the Z direction of the end 50e2 of the adhesive layer 50 on the +X direction side is greater than the thickness t1 in the Z direction of the end 50e1 of the adhesive layer 50 on the −X direction side by 1.1 times or more and 3.0 times or less.

For example, when the thickness in the Z direction of the adhesive layer 50 before deformation is 10 μm, the thickness t1 in the Z direction of the end 50e1 of the adhesive layer 50 after deformation on the −X direction side is 5 μm or more and 7.5 μm or less. The thickness t2 in the Z direction of the end 50c2 of the adhesive layer 50 after deformation on the +X direction side is 12.5 μm or more and 15 μm or less. In the description above, the “thickness in the Z direction of the adhesive layer 50 after deformation” may be replaced with a “thickness in the Z direction of the middle of the adhesive layer 50 in the X direction after deformation”.

### Method of Manufacturing Semiconductor Device According to Second Embodiment

In the embodiment, the placing of the second semiconductor chip 60 on the package substrate 10 and the first semiconductor chip 40 is performed before the adhesive layer 50 is cured. For example, when the adhesive layer 50 is a thermosetting adhesive, the placing of the second semiconductor chip 60 on the first semiconductor chip 40 and the package substrate 10 is performed before the adhesive layer 50 is heated to a cure temperature. Accordingly, by placing the second semiconductor chip 60 on the first semiconductor chip 40 and the package substrate 10 while the adhesive layer 50 is in a softened state, the adhesive layer 50 is deformed along an inclination of the second semiconductor chip 60 and the first semiconductor chip 40 is inclined along the inclination of the second semiconductor chip 60.

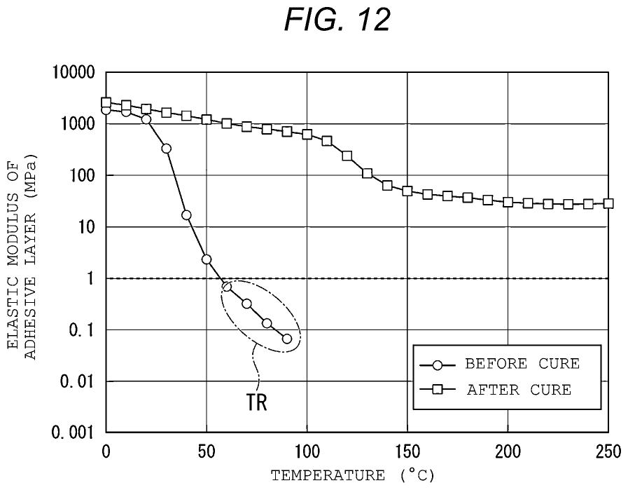

FIG. 12 is a diagram illustrating a method of manufacturing the semiconductor device according to the present embodiment. The placing of the second semiconductor chip 60 on the first semiconductor chip 40 and the package substrate 10 is performed while an elastic modulus of the adhesive layer 50 is 1 MPa or less. For example, the placing of the second semiconductor chip 60 on the first semiconductor chip 40 and the package substrate 10 is performed while a temperature is equal to or less than the cure temperature of the adhesive layer 50 and heating is performed in a predetermined temperature range in which the elastic modulus of the adhesive layer 50 is equal to or less than 1 MPa (a range indicated by a one-dot chain line TR in FIG. 12: for example, 60° C. or more and 100° C. or less).

An example of a measurement scheme for an elastic modulus illustrated in FIG. 12 is as follows.
Scheme: dynamic viscoelasticity
Device: viscoelasticity measurement device
Geometry: parallel disc diameter of 8 mm
Distortion: 0.1 to 1.4%
Temperature range: room temperature to 170° C.
Temperature raising speed: 10° C./minute
Frequency: 1 Hz
Measurement atmosphere: in nitrogen gas stream

### Advantages of Second Embodiment

As a third comparative example, a case is conceivable in which the adhesive layer 50 is not softened when the second semiconductor chip 60 is placed on the first semiconductor chip 40 and the package substrate 10. Here, when the second semiconductor chip 60 is mounted obliquely with respect to the package substrate 10, a gap between the first semiconductor chip 40 and the second semiconductor chip 60 is also inclined such that the first semiconductor chip 40 and the second semiconductor chip 60 become close in a part of the gap, and the first semiconductor chip 40 and the second semiconductor chip 60 are separated in the other part of the gap. As a result, a connection failure such as short circuit or an open failure is likely to occur in the first joints 71.

Accordingly, in the embodiment, the placing of the second semiconductor chip 60 on the first semiconductor chip 40 and the package substrate 10 is performed before the adhesive layer 50 is cured. In such configuration, when the second semiconductor chip 60 is mounted obliquely with respect to the package substrate 10, the first semiconductor chip 40 is permitted to be inclined along an inclination of the second semiconductor chip 60. Therefore, a portion in which the first semiconductor chip 40 and the second semiconductor chip 60 become too close or a portion in which the first semiconductor chip 40 and the second semiconductor chip 60 become too separated can be prevented from occurring in the gap between the first semiconductor chip 40 and the second semiconductor chip 60. As a result, it is possible to prevent a connection failure from occurring in the first joints 71. Accordingly, it is possible to reduce occurrence of a failure of the semiconductor device 1B.

In the embodiment, the placing of the second semiconductor chip 60 on the first semiconductor chip 40 and the package substrate 10 is performed while the elastic modulus of the adhesive layer 50 is 1 MPa or less. In such configuration, the adhesive layer 50 is sufficiently deformed and the first semiconductor chip 40 is easily inclined greatly along the inclination of the second semiconductor chip 60.

### Third Embodiment

Next, a third embodiment will be described. The third embodiment is different from the first embodiment in that the openings 25 of the solder resist layer 13 are large so that a positional deviation of the second joints 72 is permitted. Configurations other than configurations to be described below are the same as those of the first embodiment.

### Configuration According to Third Embodiment

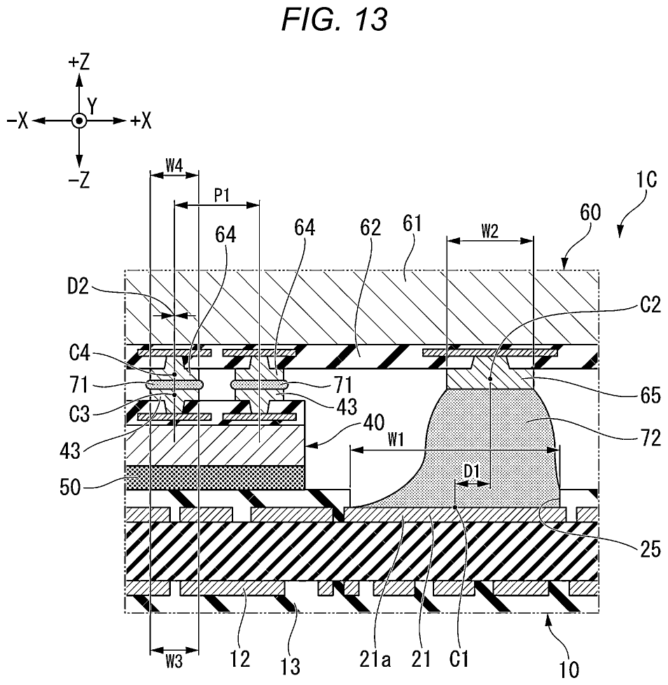

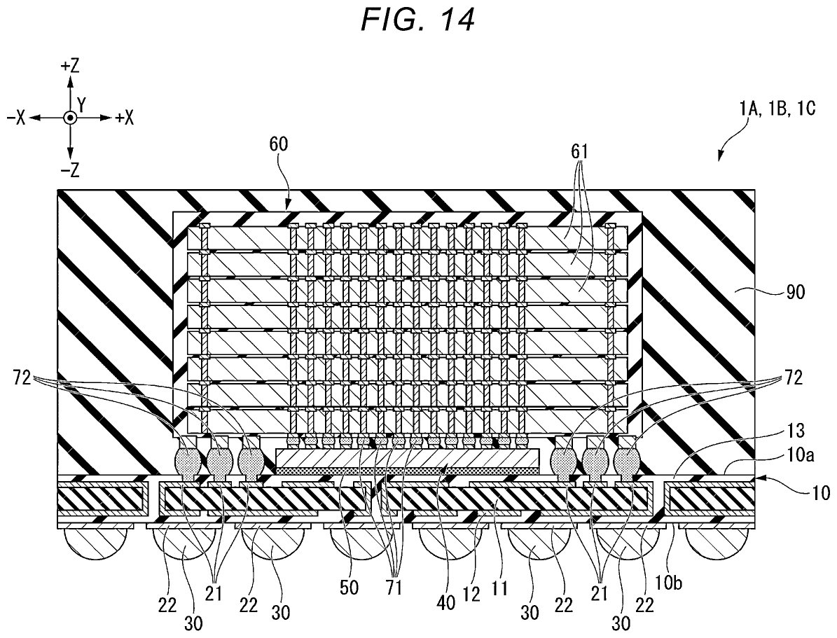

FIG. 13 is a partial sectional view illustrating a semiconductor device 1C according to the third embodiment. In the embodiment, a width W1 of the opening 25 of the solder resist layer 13 in the X direction (a width of the exposed portion 21a of the pad 21 in the X direction) is greater than a width W2 of the large pad 65 of the second semiconductor chip 60 in the X direction by 10 μm or more. In another embodiment, the width W1 of the opening 25 in the X direction is greater than the width W2 of the large pad 65 in the X direction by, for example, 20 μm or more.

From another viewpoint, in the second semiconductor chip 60, a center-to-center distance between the plurality of small pads 64 in the X direction is a first distance P1. For example, the first distance P1 is 10 μm or more and 70 μm or less. For example, the first distance P1 may be 30 μm or more and 50 μm or less. It should be noted that a specific numerical value of the center-to-center distance is not limited to the foregoing example. The width W1 of the opening 25 in the X direction is greater than the width W2 of the large pad 65 in the X direction by the first distance P1 or more.

From still another viewpoint, when each allowable tolerance of a position in the +X and −X directions at which the first semiconductor chip 40 is mounted on the package substrate 10 is a deviation amount S, the width W1 of the opening 25 in the X direction is greater than the width W2 of the large pad 65 in the X direction by twice of the deviation amount S or more. For example, when each deviation amount S that is an allowable tolerance in the +X and −X directions is 15 μm, the width W1 of the opening 25 in the X direction is greater than the width W2 of the large pad 65 in the X direction by 30 μm or more. An example of a diameter of a solder ball that is mounted on the large pad 65 and serves as the second joint 72 is 160 μm.

In the embodiment, when viewed in the Z direction, a distance D1 in the X direction between a center C1 of the opening 25 in the X direction (a center of the exposed portion 21a of the pad 21 in the X direction) and a center C2 of the large pad 65 of the second semiconductor chip 60 in the X direction is greater than a distance D2 in the X direction between a center C3 of the pad 43 of the first semiconductor chip 40 in the X direction and a center C4 of the small pad 64 of the second semiconductor chip 60 in the X direction. FIG. 13 illustrates an example in which the distance D2 is zero.

On the other hand, a width W3 of the pad 43 of the first semiconductor chip 40 in the X direction is the same as a width W4 of the small pad 64 of the second semiconductor chip 60 in the X direction, or the difference between the two is less than 10 μm.

### Method of Manufacturing Semiconductor Device According to Third Embodiment

In the embodiment, the reflow process is performed while there is the large opening 25 in the solder resist layer 13 and the second joints 72 are thus permitted to be greatly moved in the X and Y directions compared to the first joints 71. Accordingly, the second semiconductor chip 60 is aligned with respect to the package substrate 10 and the first semiconductor chip 40 through self-alignment in which the first joints 71 are used as a reference.

### Advantages of Third Embodiment

Here, as a fourth comparative example, a case in which the openings 25 of the solder resist layer 13 are not large will be described. Here, as described above in the second comparative example, when the first joints 71 and the second joints 72 are solidified in the reflow process, the tensile forces of the second joints 72 are dominant compared to the tensile forces of the first joints 71 and the position of the second semiconductor chip 60 is determined through self-alignment in which the first joints 72 are used as a reference. As a result, a connection failure of the first joint 71 or short circuit between the plurality of first joints 71 is likely to occur.

Accordingly, the width W1 of the opening 25 of the solder resist layer 13 in the X direction is greater than the width W2 of the large pad 65 of the second semiconductor chip 60 in the X direction by 10 μm or more. In such configuration, self-alignment force in which the second joints 72 are a reference is weakened and a position between the pad 43 of the first semiconductor chip 40 and the small pad 64 of the second semiconductor chip 60 does not easily deviate. As a result, it is possible to prevent a connection failure of the first joint 71 or short circuit between the plurality of first joints 71 from occurring. Accordingly, it is possible to reduce occurrence of a failure of the semiconductor device 1C.

### Modified Example of First to Third Embodiments

FIG. 14 is a sectional view illustrating the semiconductor devices 1A, 1B, and 1C according to a modified example of the first to third embodiments. As illustrated in FIG. 14, in the modified example, the insulating layer 80 that is an underfill layer is not provided. In the modified example, instead of the insulating layer 80, a part of the scaling resin portion 90 is disposed between the second surface 60b of the second semiconductor chip 60 and the first surface 10a of the package substrate 10 and between the second surface 60b of the second semiconductor chip 60 and the first surface 40a of the first semiconductor chip 40. In such configuration, the semiconductor devices 1A, 1B, and 1C similar to the first to third embodiments can be obtained.

The first to third embodiments and the modified example have been described above. Embodiments and modified examples are not limited to the above-described examples. For example, any two of the first to third embodiments may be combined and implemented, or all the first to third embodiments may be combined and implemented.

Meanwhile, in the second embodiment, the fusion point of the first joints 71 may not be different from the fusion point of the second joints 72 as in the first embodiment, and the opening 25 may not be large so that the positional deviation of the second joint 72 is permitted as in the third embodiment. In the third embodiment, the fusion point of the first joints 71 may not be different from the fusion point of the second joints 72 as in the first embodiment, and the first semiconductor chip 40 may not be disposed obliquely as in the second embodiment.

In the above-described embodiments, the examples in which the second semiconductor chip 60 includes the plurality of semiconductor memory components 61 have been described. The second semiconductor chip 60 may include only one semiconductor memory component 61 instead of the foregoing example. The semiconductor components provided in the second semiconductor chip 60 are not limited to the semiconductor memory components and may be semiconductor components other than the semiconductor memory components. In other words, the configurations of the semiconductor devices 1A, 1B, and 1C are not limited to semiconductor storage devices and may be broadly applied to various semiconductor devices.

According to at least one of the above-described embodiments, the semiconductor device according to the embodiment includes a substrate, a first semiconductor chip, an adhesive layer, a second semiconductor chip, a first joint, and a second joint. The adhesive layer fixes the substrate to the first semiconductor chip. The second semiconductor chip is disposed opposite to the substrate with respect to the first semiconductor chip and includes a first region overlapping the first semiconductor chip in a thickness direction of the substrate and a second region excluding the first region. The first joint is disposed between the first semiconductor chip and the first region of the second semiconductor chip and electrically connects the first semiconductor chip to the second semiconductor chip. The second joint is disposed between the substrate and the second region of the second semiconductor chip and electrically connects the substrate to the second semiconductor chip. A fusion point of the first joint is lower than a fusion point of the second joint. In such configuration, it is possible to reduce occurrence of a failure.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a first semiconductor chip;
an adhesive layer that is provided between the substrate and the first semiconductor chip and fixes the substrate to the first semiconductor chip;
a second semiconductor chip that is disposed opposite to the substrate with respect to the first semiconductor chip and includes a first region overlapping the first semiconductor chip in a first direction that is a thickness direction of the substrate and a second region excluding the first region;
a first joint that is disposed between the first semiconductor chip and the first region of the second semiconductor chip and electrically connects the first semiconductor chip to the second semiconductor chip; and
a second joint that is disposed between the substrate and the second region of the second semiconductor chip, is larger than the first joint in volume, and electrically connects the substrate to the second semiconductor chip, wherein
a fusion point of the first joint is lower than a fusion point of the second joint.

2. The semiconductor device according to claim 1, wherein the fusion point of the first joint is lower than the fusion point of the second joint by 5° C. or more.

3. The semiconductor device according to 2, wherein
the second semiconductor chip is disposed obliquely with respect to the substrate so that a distance between the second semiconductor chip and the substrate is greater on one side thereof than the other side thereof,
the first semiconductor chip is disposed obliquely with respect to the substrate so that a distance between the first semiconductor chip and the substrate is greater on one side thereof than the other side thereof, and
in the adhesive layer, a thickness of the adhesive layer in the first direction is greater on one side thereof than the other side thereof.

4. The semiconductor device according to claim 3, wherein the first semiconductor chip is disposed obliquely with respect to the substrate at an angle of 0.01° or more and 1.00° or less.

5. The semiconductor device according to claim 3, wherein the thickness of the adhesive layer in the first direction is greater on the one side thereof than the other side thereof by 1.1 times or more and 3.0 times or less.

6. The semiconductor device according to claim 2, wherein
the substrate includes a first pad and an insulating layer that is provided on a surface of the substrate and has an opening through which the first pad is exposed,
the second semiconductor chip includes a second pad,
the second joint is joined to the first pad and the second pad, and
a width of the opening in a second direction intersecting the first direction is greater than a width of the second pad in the second direction by 10 μm or more.

7. The semiconductor device according to claim 2, further comprising:
a plurality of joints including the first joint and disposed between the first semiconductor chip and the first region of the second semiconductor chip, wherein
the substrate includes a first pad and an opening through which the first pad is exposed,
the second semiconductor chip includes a second pad and a plurality of third pads,
the second joint is joined to the first pad and the second pad,
the plurality of joints are joined to the plurality of third pads, and
a width of the opening in a second direction intersecting the first direction is greater than a width of the second pad in the second direction by at least a first distance, which is a center-to-center distance between the plurality of third pads in the second direction.

8. The semiconductor device according to claim 1, wherein
the substrate includes a first pad and an insulating layer that is provided on a surface of the substrate and has an opening through which the first pad is exposed,
the second semiconductor chip includes a second pad,
the second joint is joined to the first pad and the second pad, and
a width of the opening in a second direction intersecting the first direction is greater than a width of the second pad in the second direction by 10 μm or more.

9. The semiconductor device according to claim 1, further comprising:
a plurality of joints including the first joint and disposed between the first semiconductor chip and the first region of the second semiconductor chip, wherein
the substrate includes a first pad and an opening through which the first pad is exposed,
the second semiconductor chip includes a second pad and a plurality of third pads,
the second joint is joined to the first pad and the second pad,
the plurality of joints are joined to the plurality of third pads, and
a width of the opening in a second direction intersecting the first direction is greater than a width of the second pad in the second direction by at least a first distance, which is a center-to-center distance between the plurality of third pads in the second direction.

10. A method of manufacturing a semiconductor device, the method comprising:
fixing a first semiconductor chip to a substrate using an adhesive;
in a second semiconductor chip that is disposed opposite to the substrate with respect to the first semiconductor chip and includes a first region overlapping the first semiconductor chip in a first direction that is a thickness direction of the substrate and a second region excluding the first region, while disposing a first joint between the first semiconductor chip and the first region and disposing a second joint that is larger than the first joint in volume between the substrate and the second region, placing the second semiconductor chip on the first semiconductor chip and the substrate with the first joint and the second joint interposed therebetween; and
connecting the first semiconductor chip to the second semiconductor chip by the first joint and connecting the substrate to the second semiconductor chip by the second joint by performing a reflow process, wherein
in the reflow process, solidification of the first joint is completed after solidification of the second joint is completed.

11. The method of manufacturing the semiconductor device according to claim 10, wherein materials for the first joint and the second joint are different and a fusion point of the first joint is lower than a fusion point of the second joint so that completion of the solidification of the first joint is performed after completion of the solidification of the second joint.

12. The method of manufacturing the semiconductor device according to claim 11, wherein the fusion point of the first joint is lower than the fusion point of the second joint by 5° C. or more.

13. The method of manufacturing the semiconductor device according to claim 12, wherein the second semiconductor chip is placed on the first semiconductor chip and the substrate before the adhesive is cured.

14. The method of manufacturing the semiconductor device according to claim 12, wherein the second semiconductor chip is placed on the first semiconductor chip and the substrate while heating the adhesive such that an elastic modulus of the adhesive is 1 MPa or less.

15. The method of manufacturing the semiconductor device according to claim 10, wherein during the reflow process, a difference in temperature between the first joint and the second joint is maintained using a heating device so that completion of the solidification of the first joint is performed after completion of the solidification of the second joint.

16. The method of manufacturing the semiconductor device according to claim 15, wherein materials for the first joint and the second joint are different.

17. The method of manufacturing the semiconductor device according to claim 16, wherein a fusion point of the first joint is lower than a fusion point of the second joint by 5° C. or more.

18. The method of manufacturing the semiconductor device according to claim 15, wherein the second semiconductor chip is placed on the first semiconductor chip and the substrate before the adhesive is cured.

19. The method of manufacturing the semiconductor device according to claim 15, wherein the second semiconductor chip is placed on the first semiconductor chip and the substrate while heating the adhesive such that an elastic modulus of the adhesive is 1 MPa or less.

20. The method of manufacturing the semiconductor device according to claim 10, wherein
the substrate includes a pad to which the second joint is joined and an insulating layer that is provided on a surface of the substrate and has an opening through which the pad is exposed, and
the reflow process is performed while the second joint is permitted to be moved in a second direction intersecting the first direction by a greater amount than the first joint.
